(19) United States
(12) Patent Application Publication
(10) Pub. No.: US 2026/0326132 A1
(43) Pub. Date: Oct. 22, 2026

(54) MULTI-INPUT MODEL-COMPENSATED SPRAYING CONTROL METHOD FOR AGRICULTURAL ROBOTS

(71) Applicant: NANJING INSTITUTE OF AGRICULTURAL MECHANIZATION, MINISTRY OF AGRICULTURE AND RURAL AFFAIRS, Nanjing (CN)

(72) Inventors: Longfei CUI, Nanjing (CN); Xinyu XUE, Nanjing (CN); Tao SUN, Nanjing (CN); Feixiang LE, Nanjing (CN); Yuxuan JIAO, Nanjing (CN); Qingqing ZHOU, Nanjing (CN); Chen CAI, Nanjing (CN); Chen CHEN, Nanjing (CN); Songchao ZHANG, Nanjing (CN); Yu QIAN, Nanjing (CN); Yang XU, Nanjing (CN); Yongkui JIN, Nanjing (CN); Suming DING, Nanjing (CN)

(73) Assignee: NANJING INSTITUTE OF AGRICULTURAL MECHANIZATION, MINISTRY OF AGRICULTURE AND RURAL AFFAIRS, Nanjing (CN)

(21) Appl. No.: 19/696,272

(22) Filed: Jun. 2, 2026

Related U.S. Application Data
(63) Continuation of application No. PCT/CN2025/113290, filed on Aug. 7, 2025.

(30) Foreign Application Priority Data
Dec. 31, 2024 (CN) 202411985658.2

(51) Int. Cl. B05B 12/00; A01C 23/04; B05B 1/16; B05B 1/20; B05B 13/00; F16K 5/06; G06F 30/28

(52) U.S. Cl. CPC B05B 12/006; A01C 23/047; B05B 1/1672; B05B 1/20; B05B 13/005; F16K 5/06; G06F 30/28

(57) ABSTRACT

Embodiments of this specification provide a multi-input model-compensated spraying control system and control method for agricultural robots, the method including: S1. building a flow and pressure control model; S2. controlling a liquid pump and an electric ball valve; S3. controlling the nozzle flow and pressure stabilization with PWM; and S4. based on a model-compensated multi-layer adaptive feedback control method, using the required flow of a system of the prescription map-based decision system and the vision-based decision system for precision spot spraying as control references, controlling a rotational speed of the liquid pump, an opening degree of the electric ball valve, and the duty ratio of the PWM proportional electromagnetic valve, adjusting the flow and the pressure by closed-loop feedback, to achieve pressure stabilization and flow control of each nozzle, and adjusting the flow and the pressure by closed-loop feedback, to ensure uniform and efficient spraying.

### CROSS-REFERENCE TO RELATED APPLICATIONS

This application is a continuation of international application number PCT/CN2025/113290, filed on Aug. 7, 2025, and claims priority to Chinese patent application number 202411985658.2, filed on Dec. 31, 2024, the entire contents of which are incorporated herein by reference.

### TECHNICAL FIELD

This specification relates to the technical field of agricultural crop protection, and specifically relates to a multi-input model-compensated spraying control method for agricultural robots.

### BACKGROUND OF THE INVENTION

Agricultural robots are a type of robots used for prevention and control of crop diseases and insect pests, can perform tasks including applying fertilizers, spraying agricultural chemicals, and monitoring diseases and insect pests according to requirements of crops, and are an important carrier for promoting development of intelligent and precision modern agriculture.

However, existing agricultural robots often have problems of chemical waste and uneven spraying in a spraying process, and cannot precisely distribute a spraying quantity based on geographic information and crop conditions, resulting in low agricultural chemical utilization, high operating costs, and unnecessary negative effects on the ecological environment. Therefore, there is an urgent need for a multi-input model-compensated spraying control system and control method for agricultural robots, which can achieve precise modeling and optimized control of the spraying process, thereby effectively reducing the cost of agricultural chemical use, and improving the intelligence level and environmental friendliness of spraying operations.

### SUMMARY

Embodiments of this specification provide a multi-input model-compensated spraying control method for agricultural robots, to solve the problems posed in the above background.

To solve the above technical problems, one or more embodiments of this specification provide a multi-input model-compensated spraying control method for agricultural robots, including the following steps:
S1. building a flow and pressure control model, the flow and pressure control model being constructed as follows:
1) building a nozzle flow model:
a nozzle flow Q_{nozzle} is controlled by both a duty ratio D of a PWM proportional electromagnetic valve and a pressure P_{supply} of a main pipeline, and is calculated as follows:

Q_{nozzle}=k_{Q}·D·P_{supply};
where k_{Q} is a flow gain coefficient and is related to nozzle structural parameters; D is the duty ratio of the PWM proportional electromagnetic valve and is in a range of [0, 1]; and P_{supply} is the pressure of the main pipeline;
2) performing distribution of a required flow of a system and the nozzle flow:
without a prescription map-based decision system or a vision-based decision system for precision spot spraying, a fixed spraying quantity per mu is used, and the required flow Q_{required} of a system is determined by a unit area spraying quantity Q_{target}, a breadth W of a spray boom, and a vehicle speed v, and is calculated as follows:

Q_{required}=Q_{target}·W·v;
with the prescription map output system and the vision-based decision system for precision spot spraying, Q_{required} is equal to the sum of the target flows of all nozzles;
S2. controlling a liquid pump and an electric ball valve;
S3. controlling the nozzle flow and pressure stabilization with PWM; and
S4. based on a model-compensated multi-layer adaptive feedback control method, using the required flow of a system of the prescription map-based decision system and the vision-based decision system for precision spot spraying as control references, controlling a rotational speed of the liquid pump, an opening degree of the electric ball valve, and the duty ratio of the PWM proportional electromagnetic valve, adjusting the flow and the pressure by closed-loop feedback, to achieve pressure stabilization and flow control of each nozzle, and adjusting the flow and the pressure by closed-loop feedback, to ensure uniform and efficient spraying.

### BRIEF DESCRIPTION OF THE DRAWINGS

This specification will be further described through exemplary embodiments, and the exemplary embodiments will be described in detail with accompanying drawings. These embodiments are not limiting, and in these embodiments, the same numeral represents the same structure, where:

FIG. 1 is an exemplary flowchart of a multi-input model-compensated spraying control method for agricultural robots according to some embodiments of this specification;

FIG. 2 is a principle diagram of composition of a multi-input model-compensated spraying control system for agricultural robots according to some embodiments of this specification;

FIG. 3 is a composition flowchart of a multi-input model-compensated spraying control system for agricultural robots according to some embodiments of this specification;

FIG. 4 is a schematic diagram of division of a field of view of an image during vision-based precision spot spraying according to some embodiments of this specification; and

FIG. 5 is a schematic diagram of a vision-based spraying triggering algorithm based on a dynamic virtual line of a spray boom for precision spot spraying according to some embodiments of this specification.

### DETAILED DESCRIPTION OF THE INVENTION

In order to illustrate the technical solutions in embodiments of this specification more clearly, the following briefly introduces the accompanying drawings required in the embodiments. It is apparent that the accompanying drawings in the following description illustrate merely some examples or embodiments of this specification, and a person of ordinary skill in the art may apply this specification to other similar scenarios based on these accompanying drawings without creative efforts. Unless being obvious from a language environment or otherwise specified, the same numeral in the figures represents the same structure or operation.

It should be understood that the terms “system,” “apparatus,” “unit,” and/or “module” used in this specification are a method for distinguishing different components, elements, parts, or assemblies at different levels. However, if other words can achieve the same purpose, the above terms can be replaced with other expressions.

As described in this specification and claims, unless the context clearly indicates an exception, words such as “a”, “an”, and/or “one”, do not specifically refer to the singular, but may also include the plural. Generally speaking, the terms “include” and “comprise” only indicate the steps and elements that have been clearly identified, and these steps and elements do not constitute exclusive lists, but a method or device may also contain other steps or elements.

In this specification, a flowchart is used to illustrate operations performed by a system according to the embodiments in this specification. It should be understood that the preceding or following operations may not be performed precisely in order. On the contrary, the steps can be processed in reverse order or simultaneously. Also, other operations can be added to these processes, or one or more operations can be removed from these processes.

In the following description, a large number of specific details are given to provide a more complete understanding of the present disclosure. However, it is apparent to a person skilled in the art that the present disclosure may be implemented without one or more of these details. In other examples, to avoid confusion with the present disclosure, descriptions of some technical features well-known in the art are omitted.

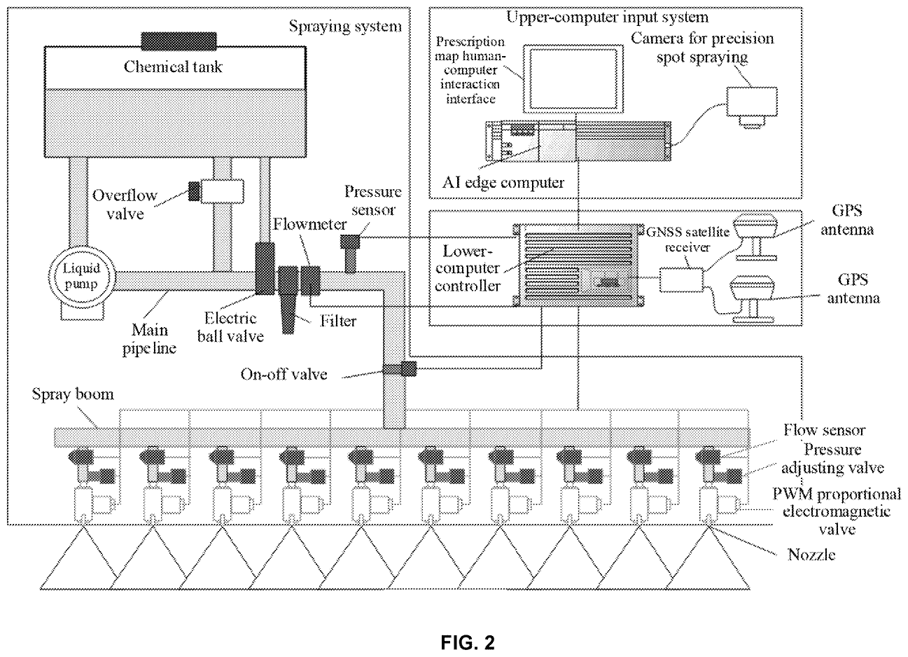

FIG. 2 is a principle diagram of composition of a multi-input model-compensated spraying control system for agricultural robots according to some embodiments of this specification.

Some embodiments of this specification provide a multi-input model-compensated spraying control system for agricultural robots (hereinafter referred as a spraying control system), including an upper-computer input system, a lower-computer controller, and a spraying system. The upper-computer input system is based on an image processing unit of an AI edge computing platform, performs target identification by using a deep learning model, and extracts key information of a target in real time, the key information including boundaries, center positions, density, and the size, growth state, and health condition of crops. The lower-computer controller receives related information of a target transmitted by the upper-computer, and dynamically controls execution elements based on a real-time traveling speed of an agricultural robot, sensor data of the spraying system, and key information of target crops or weeds by using a dynamic advance adjustment strategy of a virtual line of a spray boom, to precisely spray the target. The execution elements include three elements: a liquid pump, an electric ball valve, and a PWM proportional electromagnetic valve. The spraying system includes a chemical tank, a liquid pump, a pressure sensor, an on-off valve, an electric ball valve, an overflow valve, a PWM proportional electromagnetic valve, and a nozzle array.

In some embodiments, as shown in FIG. 2, the spraying system may further include a main pipeline, a flow meter, a filter, a spray boom, nozzles, a pressure regulating valve, and a flow sensor.

In some embodiments, as shown in FIG. 2, an outlet of the chemical tank is connected to an inlet of the liquid pump, and an outlet of the liquid pump is connected to the main pipeline. An overflow valve is arranged at the outlet of the liquid pump to provide pressure relief protection when the pressure in the main pipeline exceeds a preset threshold. The main pipeline is sequentially connected with the electric ball valve, the filter, the flow meter, the pressure sensor, and the on-off valve along a chemical liquid flow direction, to achieve control of on/off of a chemical liquid in the main pipeline, filtration of impurities, and detection of flow and pressure. The end of the main pipeline is connected to the spray boom, and the spray boom is connected to the nozzles through nozzle branches. Each nozzle branch is sequentially provided with the flow sensor, the pressure regulating valve, and the PWM proportional electromagnetic valve. For more content about the spraying system, refer to relevant descriptions below.

In some embodiments, the spraying control system adopts a distributed two-level perception architecture, and the distributed two-level perception architecture includes a main pipeline level and an execution end level. The main pipeline level obtains an overall chemical liquid output state of the spraying system by means of the flow meter and the pressure sensor mounted on the main pipeline, to provide a system level working condition reference for the lower-computer controller. The execution end level obtains independent operating parameters of each execution end (each nozzle) in real time by means of the pressure sensor and the flow sensor mounted on each nozzle branch.

An agricultural robot refers to an intelligent device that can autonomously or semi-autonomously complete agricultural tasks, and is used for prevention and control of crop diseases and insect pests. The agricultural tasks include sowing, spraying, fertilization, picking, and patrolling.

The upper-computer input system is a unit configured to obtain a prescription map or a target and perform calculations and data processing.

In some embodiments, as shown in FIG. 2, the upper-computer input system includes a prescription map human-computer interaction interface, an AI edge computer, and a camera for precision spot spraying. The prescription map human-computer interaction interface refers to a software interface used to achieve information interaction between a user and the spraying control systems. The user refers to a subject using the spraying control system.

The AI edge computing platform refers to a device that processes and intelligently analyzes collected image data or other data. In some embodiments, the AI edge computing platform may be the AI edge computer. The AI edge computer may be an embedded AI computing device or an industrial computer, including but not limited to an edge computing device equipped with a GPU or an AI accelerator chip, for example, NVIDIA Jetson AGX Xavier, NVIDIA Jetson Nano, NVIDIA Jetson Orin, and Google Coral Dev Board.

The image processing unit refers to a functional unit used to receive, process, analyze, and identify image data collected by the camera for precision spot spraying. In some embodiments, the image processing unit is integrated in the AI edge computing platform.

The target refers to an object that needs to be identified and sprayed in a spraying process of an agricultural robot. In some embodiments, the target includes crops, weeds, and pests.

The lower-computer controller (also known as a controller) refers to a device that controls the spraying system. In some embodiments, the lower-computer controller is connected in communication with the upper-computer input system and performs operations such as flow regulation, pressure regulation, and nozzle opening and closing control based on relevant information sent by the upper-computer.

In some embodiments, the lower-computer controller adopts a hardware architecture based on a DSP C2000 series MCU, and integrates a plurality of functional modules to ensure high-precision spraying control and real-time data processing. The lower-computer controller integrates functional modules such as an ADC module, an EQEP module, a PWM module, a GPIO interface, and an RS232 communication interface that work together to achieve precise collection and control of the pressure and the flow.

In some embodiments, the lower-computer controller collects data of the pressure sensor in real time via the integrated ADC module. The MCU provides an ADC with a resolution of 16 bits. The sampling rate of each ADC channel may be 1.1 MSPS, and up to 12 external input channels are supported. The high-precision data helps the system monitor the pressure change in the spraying system in real time, to ensure the stability and uniformity of the spraying process. Precise pressure monitoring provides a reliable data support for controlling the spraying precision.

In some embodiments, the lower-computer controller uses the EQEP (enhanced quadrature encoder pulse) module to collect feedback data of the flow sensor. The EQEP module provides high-precision flow feedback to help the controller precisely adjust the spraying quantity. By means of such feedback, the system can adjust the nozzle flow in real time, to ensure the consistency and precision of the spraying effect and reduce waste of a chemical liquid.

In some embodiments, the lower-computer controller performs communication and control signal transmission with the upper-computer via the RS232 interface to ensure timely transmission of control signals. The lower-computer controller receives target identification data transmitted by the AI edge computer via the RS232 interface, and precisely controls opening and closing of a nozzle based on the position and size of the target. In some embodiments, a control signal of the PWM proportional electromagnetic valve of each nozzle is generated by the PWM module of the lower-computer controller. A control signal generated by the PWM module may be used to adjust opening and closing of a nozzle, and control the spraying quantity of a chemical liquid. Fine PWM signal control enables the spraying quantity to be adjusted in real time according to requirements.

In some embodiments, the lower-computer controller precisely controls a proportional flow valve via linkage of a GPIO pin and an MOS transistor amplifier circuit. The GPIO pin receives a signal generated by the MCU, and the MOS transistor amplifies the signal to drive the opening degree of the proportional flow valve, to ensure that the flow and the pressure are precisely controllable in the spraying process, and ensure that each nozzle is precisely adjusted based on real-time feedback data, thereby avoiding waste of a chemical liquid and damage of crops.

In some embodiments, the lower-computer controller is provided with 24 enhanced PWM channels, and can precisely control the flow and the pressure in the spraying process. By adjusting the PWM frequency and the duty ratio, the system can finely control the spraying quantity of a nozzle, to ensure the uniformity and stability of distribution of a chemical liquid. The high-resolution PWM channels ensure the response speed and precision of the nozzle, to adapt to dynamically changing requirements for spraying.

In some embodiments, the lower-computer controller is also connected in communication with a high-precision positioning system to obtain the latitude and longitude positions of a nozzle. The high-precision positioning system includes a global navigation satellite system (GNSS) satellite receiver and a global positioning system (GPS) antenna.

The spraying system refers to an execution apparatus that achieves storage and transport of a chemical liquid, pressure regulation, and spraying operations.

The chemical tank refers to a container for storing a chemical liquid. The liquid pump refers to a power apparatus that transports a chemical liquid from the chemical tank to a pipeline and provides transport pressure. The main pipeline refers to a fluid transport channel used to transport a chemical liquid and communicate with various functional components. The flow meter refers to a device used to monitor the flow of a chemical liquid in the main pipeline. The filter refers to an apparatus that filters impurities from a chemical liquid to prevent nozzle clogging. The spray boom refers to an apparatus that transport a chemical liquid from the main pipeline to each nozzle in a nozzle array through the nozzle branches.

The nozzle branch refers to a branch pipeline that is led out from the spray boom and communicates with each nozzle to transport a chemical liquid to the corresponding nozzle. In some embodiments, the main pipeline is communicated with the spray boom to transport a chemical liquid transported by the liquid pump to the spray boom. The spray boom is provided with a plurality of nozzle branches along the length direction of the spray boom, and each nozzle branch is communicated with a corresponding nozzle in the nozzle array to distribute a chemical liquid to each nozzle.

The flow sensor is a sensor used to detect the flow of a chemical liquid in a nozzle branch of the spraying system and output a corresponding flow signal. The pressure sensor is a sensor used to detect the pressure of a chemical liquid in the main pipeline and output a pressure signal. The on-off valve is a valve apparatus used to control the on/off state of a branch of a chemical liquid pipeline.

The electric ball valve refers to a valve apparatus that adjusts the flow area of a pipeline by driving a spherical valve core to rotate by a motor. The overflow valve refers to a valve apparatus that automatically releases part of a chemical liquid to maintain safety of the spraying system when the pipeline pressure exceeds a set value. The pressure regulating valve refers to a valve apparatus used to regulate the pressure of a chemical liquid in the nozzle branches corresponding to the nozzles.

The PWM proportional electromagnetic valve is an electromagnetic valve apparatus that controls the opening degree of a valve by means of a pulse-width modulation signal to regulate the flow of a chemical liquid.

The nozzle array is a spraying assembly formed by a plurality of nozzles arranged at preset intervals. The preset intervals can be preset by those skilled in the art based on experience.

In some embodiments, FIG. 2 may be a control unit of the spraying control system. A modular structure with 10 or N nozzles as a control unit is used, and each control unit may be independently operated and precisely controlled. On a large agricultural robot, the number of control units with the same structure as shown in FIG. 2 can be proportionally increased according to actual needs, and asynchronous operation of the control units can be achieved by means of matrix control signals. The lower-computer controller can switch the working states of any number of control units in real time according to the requirement of a working breadth, thereby achieving segmented independent spray or full breadth operation. For example, for a common 27-55 m boom sprayer, a plurality of control units may be flexibly arranged to achieve zone control of a spray boom across the full breadth. The plurality of control units achieve state synchronization, cooperative control, and remote diagnosis via CAN bus communication, and effectively improve the scalability and networking capability of the spraying control system.

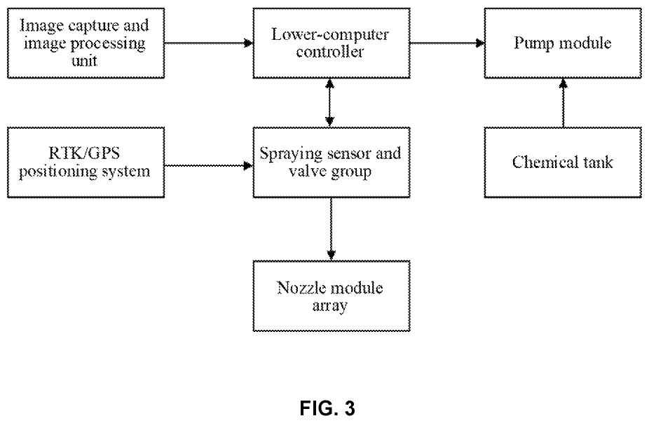

FIG. 3 is a composition flowchart of a multi-input model-compensated spraying control system for agricultural robots according to some embodiments of this specification.

In some embodiments, as shown in FIG. 3, the spraying control system includes an image collection and processing unit, a lower-computer controller, a pump module, a chemical tank, a spraying sensor, a valve block, an RTK/GPS positioning system, and a nozzle module array. For more content about the lower-computer controller and the chemical tank, refer to FIG. 2 and relevant descriptions thereof.

The image collection and processing unit refers to a functional unit that collects image data and performs data processing. In some embodiments, the image collection and processing unit can be integrated into the upper-computer input system to obtain images of an operating region in real time, and identify a target and spatial coordinates thereof by a target detection algorithm.

The pump module is used to provide a chemical liquid flow with a controlled pressure. In some embodiments, the pump module is a functional unit that supports motor drive or hydraulic drive, can receive a speed control instruction from the lower-computer controller to achieve rough pressure regulation, and transmits the adjusted chemical liquid flow to the valve block and the nozzle module at the back of a pipeline through the pipeline. In some embodiments, the pump module may include a liquid pump. In some embodiments, the pump module is driven by a motor or a hydraulic motor.

In some embodiments, the lower-computer controller serves as a core control unit, and can be connected to sub-modules through a bus (e.g., CAN and RS485) or a GPIO port to perform parallel multi-task processing and timing scheduling.

The spraying sensor refers to a sensor that is mounted on the main pipeline or a nozzle branch and used to monitor the pressure or the flow of a chemical liquid in real time, and the valve block refers to a valve block for controlling the on/off of a chemical liquid.

The RTK/GPS positioning system is a functional unit used to obtain the absolute geographic coordinates, speed, and heading information of an agricultural robot in real time. In some embodiments, the RTK/GPS positioning system can serve as a high-precision positioning system.

The nozzle module array refers to an execution end formed by a plurality of independent nozzles arranged at certain intervals.

In some embodiments, the nozzle module array may include the nozzle array as shown in FIG. 2.

In some embodiments, the image collection and processing unit collects images in real time and identifies a target by an algorithm. Meanwhile, the RTK/GPS positioning system can obtain the absolute geographic coordinates, speed, and heading information of an agricultural robot in real time. The two portions of data are sent to the lower-computer controller. Based on the data, the lower-computer controller calculates which nozzle is to be opened, how long the nozzle is delayed to be opened, and how long the nozzle is to be opened when the agricultural robot moves to a certain location at a certain speed. When the agricultural robot reaches a designated location, the lower-computer controller sends an instruction to the spraying sensor and the valve block to control the PWM proportional electromagnetic valve of a corresponding channel to be opened. At the same time, the controller sends a control signal to the pump module to regulate the rotational speed and maintain a stable spray pressure. A chemical liquid is pumped out of the chemical tank by the pump, passes through the opened valve block, and finally is sprayed out of the nozzle module array against a target. In the spraying process, the spraying sensor monitors the pressure and the flow in the pipeline in real time and feeds back the data to the lower-computer controller in real time. The lower-computer controller dynamically regulates the rotational speed of the pump based on a feedback signal, to ensure stable pressure and precise spraying throughout an entire spraying process, and form a complete closed-loop control system.

In some embodiments, the dynamic advance adjustment strategy of a virtual line of a spray boom dynamically optimizes a spraying triggering time with reference to a vehicle speed, a spraying valve-opening delay, and a fog droplet fall time, to ensure precise coverage of a target in different operating conditions, maximize the utilization of a chemical liquid, and reduce waste. The upper-computer input system continuously calculates and adjusts an advance amount according to real-time data, to ensure that the spraying control system can precisely trigger spraying in various environmental conditions.

The dynamic advance adjustment strategy of the virtual line of the spray boom refers to a control strategy for predicting a corresponding spraying position on the ground of the spray boom in advance based on factors including the vehicle speed, the spraying valve-opening delay, and the fog droplet fall time of an agricultural robot in a spraying process, and dynamically moving the corresponding virtual line of the spray boom forward along the traveling direction, thereby matching a spraying control position with a position to be sprayed.

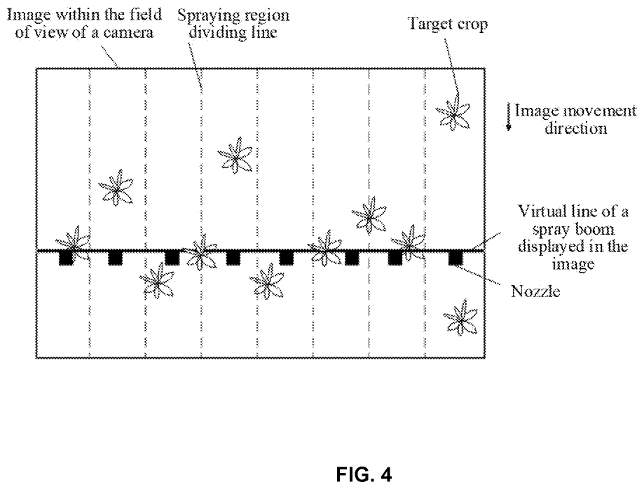

FIG. 4 is a schematic diagram of division of a field of view of an image during vision-based precision spot spraying according to some embodiments of this specification.

In some embodiments, the field of view of a camera of the spraying control system is divided into a regions, and as shown in FIG. 4, each region corresponds to one nozzle to achieve independent spraying control. An image capture device collects image data of the front crop regions in real time, and transmits the image data to an AI edge computing platform for processing. The AI edge computing platform subscribes to an image data stream in an ROS framework, executes a target identification model, and identifies the position and size of a target in each region in real time, to provide precise position information for a spraying decision. For more content about the target identification model, refer to relevant descriptions below.

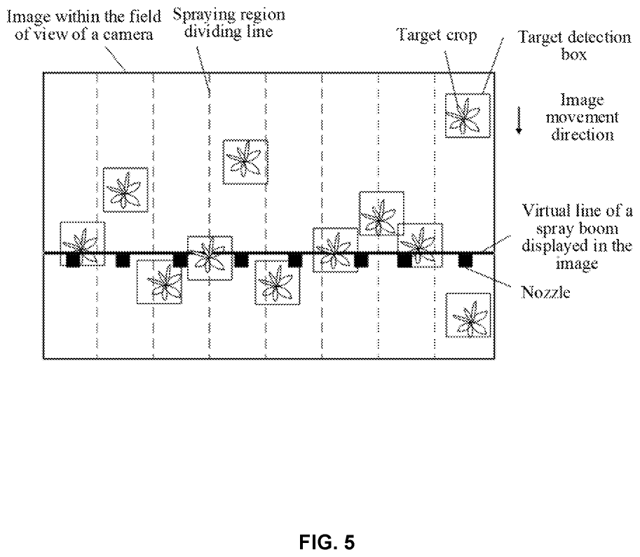

FIG. 5 is a schematic diagram of a vision-based spraying triggering algorithm based on a dynamic virtual line of a spray boom for precision spot spraying according to some embodiments of this specification.

In some embodiments, as shown in FIG. 5, a virtual line represents the position of the spray boom in an image coordinate system of the camera. The spraying control system matches a target detected in the image data with a nozzle on the spray boom, and generates a control data frame for the PWM proportional electromagnetic valve, thereby precisely controlling the nozzle to spray the target. The virtual line divides the field of view into n+1 regions by n spraying region dividing lines. Each virtual line is divided into several segments by the spraying region dividing lines. Each spraying region corresponds to one PWM proportional electromagnetic valve on the spray boom. The length of each spraying region is the average spraying breadth of each electromagnetic valve.

In an advancing process of the sprayer, the ground image moves downwards, and the upper-computer input system detects in real time via a deep learning target detection algorithm and draws a prediction box of the target. The virtual line is used to determine whether the target enters the spraying region. When the prediction box of the target intersects the virtual line of the spray boom in the image, it indicates that the target enters a corresponding spraying interval. The spraying time is determined according to the intersection between the virtual line of the spray boom in the image and the position of the target crop.

When a line connected between midpoints in the front end of the prediction box of the target intersects with the virtual line of the spray boom adjusted in advance in the image, the target identification model predicts information of the target in each spraying region, i.e., the information such as boundaries, center positions, density, and the size, growth state, and health condition of crops. Pixel area data is transmitted to the lower-computer controller via a communication interface. After receiving the pixel area data, the lower-computer converts the data into a target flow signal of a nozzle in a corresponding region. In some embodiments, the target flow value of the nozzle is in positive correlation with the information of the target, and a mapping relationship therebetween is obtained by experimental data regression. By such a mechanism, the spraying control system can adjust the chemical spray volume in real time according to the size of the crops to ensure precise spraying.

To ensure the precision, the spraying control system uses a dynamic advance adjustment strategy of a virtual line of a spray boom. Due to impact of the traveling speed of an agricultural robot, the virtual line needs to be dynamically adjusted in advance based on the vehicle speed, the spraying valve-opening time, and the fog droplet fall time. As the vehicle speed increases, an advance amount of the virtual line correspondingly increases to trigger spraying in advance and avoid a spraying delay. In addition, the spraying valve-opening response time and the time required for spraying a chemical liquid from the nozzle may also affect adjustment of the advance amount, to ensure that the chemical liquid is precisely sprayed above the target.

The spraying valve-opening response time refers to a period of time since the instruction is sent until the PWM proportional electromagnetic valve is opened, when the lower-computer controller sends an opening instruction to the PWM proportional electromagnetic valve. The fog droplet fall time refers to a period of time since a chemical liquid is sprayed from a nozzle until the chemical liquid falls onto the surface of a target.

A physical advance range D_{phys} is a physical distance of the spray boom relative to the camera. In some embodiments, the D_{phys} is calculated with the vehicle speed v_{car}, the spraying valve-opening time tₒₚₑₙ, and the fog droplet fall time t_{fall} of an agricultural robot. In this case, the physical advance range refers to the actual distance of the spray boom from a reference point of a camera coordinate system to the lower part of the spray boom, and a calculation equation for the physical advance range is shown as equation (1):

D_{phys}=v_{car}×(tₒₚₑₙ+t_{fall}) (1)
in equation (1), v_{car} is the vehicle speed; tₒₚₑₙ is the spraying valve-opening time; t_{fall} is the fog droplet fall time.

The vehicle speed refers to the traveling speed of the agricultural robot. In some embodiments, the vehicle speed may be determined by a motion sensor mounted on the agricultural robot, such as a wheel speed sensor, an inertial measurement unit, or a high-precision positioning system (RTK/GPS). In some embodiments, the spraying valve-opening time may be determined by calibrating the PWM proportional electromagnetic valve. In some embodiments, an average fall time of spray particles from a nozzle to the ground may be measured experimentally as the fog droplet fall time.

To convert the physical advance range into an advance pixel distance in the image coordinate system, a geometric relationship of the camera may be used without the need of a depth map. If the focal length of the camera is assumed as f, and a ground projection width along the advancing direction of the agricultural robot, i.e., a field width, is assumed as W_{view}, then the advance pixel distance Dₚᵢₓ and the physical advance range D_{phys} have a relationship shown as equation (2):

$${D}_{pix} = \frac{f \times {D}_{phys}}{{W}_{view}} \qquad ( 2 )$$

in equation (2), f is the focal length of the camera; D_{phys} is the physical advance range; W_{view} is the width of the field of view of the camera; and Dₚᵢₓ is the advance pixel distance.

The advance pixel distance refers to the pixel distance of the physical advance range in the image coordinate system.

In some embodiments, the focal length of the camera may be determined by camera calibration, for example, by a checkerboard calibration method.

The width of the field of view refers to the width of a projection of the field of view of the camera on the ground. In some embodiments, the width of the field of view is measured experimentally, i.e., after the camera is mounted, a corresponding actual width of the ground is measured within the field of view of the camera. In some embodiments, the physical advance range may be determined by equation (1).

In some embodiments of this specification, the advance adjustment mechanism of the virtual line dynamically optimizes a spraying triggering time with reference to the vehicle speed, the spraying valve-opening delay, and the fog droplet fall time, to ensure precise coverage of the target in different operating conditions, maximize the utilization of a chemical liquid, and reduce waste. The upper-computer continuously calculates and adjusts an advance amount according to real-time data, to ensure that the spraying control system can precisely trigger spraying in various environmental conditions.

By means of the above hardware design and control strategy, the spraying control system can achieve efficient and precise spraying control in a complex field environment. Combination of global decision of the upper-computer input system and precise execution of the lower-computer controller ensures the real-time performance and precision of spraying, reduces waste of agricultural chemicals, and satisfies high requirements of precise agriculture on operation precision and efficiency.

In some embodiments, the image processing unit is controlled by the AI edge computing platform, mounts the target identification model, performs real-time image processing and target identification based on visual identification and a dynamic control strategy, optimizes image analysis and data processing by a parallel computing acceleration technology, ensures high real-time performance and high precision of image identification, and adapts to precise identification and dynamic control of different types of targets.

In some embodiments, the camera for precision spot spraying may use an Intel D435i binocular camera, i.e., the Intel D435i binocular camera is used as the image capture device. The Intel D435i binocular camera has a high-resolution depth perception function, a built-in IMU, and a wide dynamic range sensor, can provide clear images in a bright light or weak light condition, and can precisely obtain distance information of a target by the depth perception technology. In addition, the camera needs to be kept parallel to the ground when mounted, and a field of view angle is dynamically adjusted according to a traveling path of an agricultural robot, to ensure comprehensive coverage of a crop region, and provide visual input for subsequent target identification.

The target identification model refers to a model used for identifying targets.

In some embodiments, the target identification model may be a deep learning model such as YOLO and Unet, and is developed with Python or C language and deployed in the upper-computer input system. The target identification model performs efficient identification on targets by real-time image processing to ensure the spraying precision. In a model training process, the target identification model performs supervised learning by using a large amount of labeled training data, to ensure that the target identification model can precisely distinguish crops from a background in a complex environment. The labeling of training samples mainly includes labeling of target images, soil, and vacancy regions.

In some embodiments, the training data includes diversified samples having different lighting conditions, crop densities, and shapes, and is input into the target identification model for training after data enhancement. The model training optimizes the identification precision by gradually adjusting a weight of a convolutional neural network, to ensure that a crop identification task can be handled in different environments. The training process uses cross validation and a real-time feedback mechanism, can optimize the generalization capability of the model, and enables the model to work stably in a plurality of complex lighting and environment conditions.

In a deployment stage, the target identification model is integrated into the upper-computer input system, and is used to achieve real-time image processing, environment adaptive adjustment, and target data transmission. In some embodiments, the upper-computer input system receives a real-time image stream from the binocular camera, and uses the target identification model to segment an image into targets, soil, and vacancy regions, to identify the positions, shapes, and size of the targets in real time. The identification results include feature information such as the region, area, and density of crops, and then are transmitted to the lower-computer controller via an RS232 interface.

To deal with changes in light, in some embodiments, the upper-computer input system includes automatic exposure adjustment and image contrast enhancement, to ensure the identification stability in a bright light or weak light condition.

In some embodiments of this specification, by the environment adaptive processing, the upper-computer input system can maintain a high identification precision in a dynamically changing lighting condition. The identified data of a target not only helps the spraying control system to precisely position crops, but also optimizes the spraying quantity and coverage of a chemical liquid, thereby reducing waste of agricultural chemicals.

In some embodiments, when a target is sprayed, the spraying time is dynamically adjusted by using a high-precision positioning system in combination with real-time motion state feedback, to precisely spray the target.

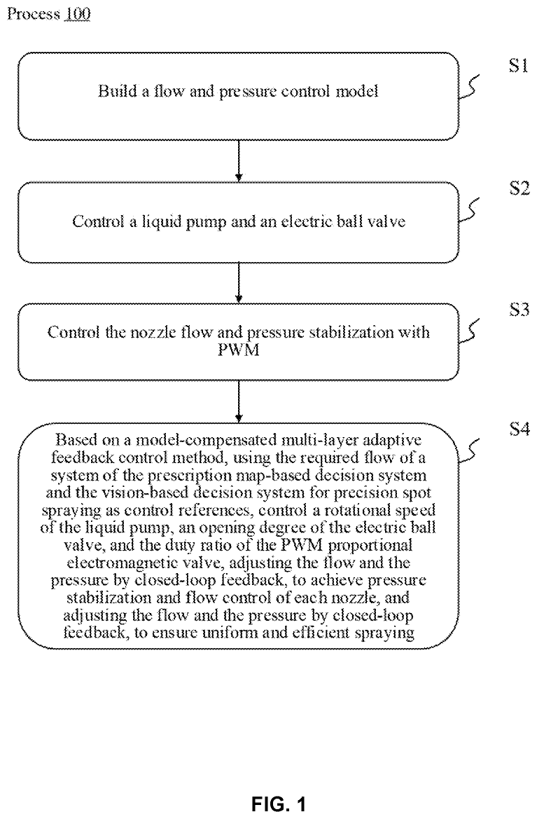

FIG. 1 is an exemplary flowchart of a multi-input model-compensated spraying control method for agricultural robots according to some embodiments of this specification. As shown in FIG. 1, a process 100 includes S1 to S4. In some embodiments, the process 100 may be executed by a spraying control system. For more content about the spraying control system, refer to FIG. 2 to FIG. 3 and relevant descriptions thereof.

An embodiment of this specification provides a multi-input model-compensated spraying control method for agricultural robots, including the following steps:
S1. build a flow and pressure control model;
S2. control a liquid pump and an electric ball valve;
S3. control the nozzle flow and pressure stabilization with PWM; and
S4. based on a model-compensated multi-layer adaptive feedback control method, using a required flow of a prescription map-based decision system and a vision-based decision system for precision spot spraying as control references, control a rotational speed of the liquid pump, an opening degree of the electric ball valve, and a duty ratio of a PWM proportional electromagnetic valve, to achieve pressure stabilization and flow control of each nozzle, and adjust the flow and the pressure by closed-loop feedback, to ensure uniform and efficient spraying.

In some embodiments, the flow of the nozzle is adjusted by the PWM proportional electromagnetic valve, the duty ratio is in a nonlinear functional relationship with the flow, and the target flow of each nozzle may be determined by a spraying mode (e.g., prescription map-based spraying or a vision-based precision spot spraying). In the spraying process, the actual flow of each nozzle is measured in real time, the flow error is calculated, and the duty ratio for the nozzle is adjusted to make the flow of the nozzle close to a desired value. In addition, the duty ratio for the nozzle is dynamically adjusted based on the real-time pressure of a main pipeline, to ensure that the flow is not affected by pressure fluctuation.

In some embodiments, in S1, the flow and pressure control model is built by the following S1.1 to S1.2:

### S1.1. Build a Nozzle Flow Model:

the nozzle flow Q_{nozzle} is controlled by both the duty ratio D of the PWM proportional electromagnetic valve and the pressure P_{supply} of a main pipeline, and is calculated by the following equation (3):

Q_{nozzle}=k_{Q}·D·P_{supply}; (3)

in equation (3), k_{Q} is a flow gain coefficient and is related to nozzle structural parameters; D is the duty ratio of the PWM proportional electromagnetic valve and is in a range of [0, 1]; and P_{supply} is the pressure of the main pipeline.

In some embodiments, the flow gain coefficient is related to the nozzle structural parameters, and may be determined by experimental calibration. For example, under the conditions of different duty ratios and pressures of the main pipeline, the actual flow of a nozzle is measured by a weighing method or a high-precision flow meter, and linear or nonlinear fitting is performed based on least squares to obtain the flow gain coefficient.

In some embodiments, the duty ratio is a control variable calculated and generated in real time by the lower-computer controller based on a target spraying quantity algorithm, and is converted into a corresponding electrical signal by a PWM module (e.g., an ePWM module) inside the controller and sent to the PWM proportional electromagnetic valve. For more content about the PWM module, refer to relevant descriptions above.

In some embodiments, the pressure of the main pipeline may be determined by a pressure sensor mounted on the main pipeline.

### S1.2. Perform Distribution of the Required Flow of the System and the Nozzle Flow:

Without the prescription map-based decision system or the vision-based decision system for precision spot spraying, a fixed spraying quantity per mu is used, and the required flow Q_{required} of the system is determined by a unit area spraying quantity Q_{target}, the breadth W of the spray boom, and the vehicle speed v, and is calculated by the following equation (4):

Q_{required}=Q_{target}·W·v; (4)

The unit area spraying quantity refers to the quantity of a chemical liquid that needs to be sprayed per unit area. In some embodiments, the unit area spraying quantity is set by a user based on a crop type or operation requirements in the upper-computer input system.

The breadth of the spray boom refers to an effective spraying width formed by spraying ranges of the nozzles in the horizontal direction when the spray boom is in operation. In some embodiments, the breadth of the spray boom may be calculated by multiplying an installation spacing between the nozzles by the total number of the nozzles currently opened. In some embodiments, the breadth of the spray boom may be determined by referring to a technical manual of the spray boom.

In some embodiments, the vehicle speed may be measured in real time by an RTK/GPS positioning system or an encoder mounted on an axle of an agricultural robot, and fed back to the lower-computer controller to achieve dynamic correction of the required flow.

With the prescription map-based decision system and the vision-based decision system for precision spot spraying, the required flow Q_{required} of the system is equal to the sum of the target flows of all nozzles.

In some embodiments of this specification, the multi-input model-compensated spraying system and control method are provided, which support three operation modes: vision-based precision spot spraying, prescription map-based spraying, and spraying with a fixed quantity per mu, and significantly improve the precision and adaptability of agricultural spraying. The prescription map-based spraying achieves precise distribution of the spraying quantity in space by precisely calculating the quantity of chemical demanded by crops in different plots and with reference to high-precision geographical information and the growth state of the crops. The vision-based precision spot spraying is based on a real-time image identification technology, to dynamically identify targets and adjust the spraying quantity, ensure that the chemical only acts on a target region, and avoid ineffective spraying and resource waste.

In some embodiments, in S2, the liquid pump and the electric ball valve are controlled by the following S2.1 to S2.3:

### S2.1. Model a Spraying System:

a flow of the liquid pump and the rotational speed of the liquid pump have a relationship shown as equation (5):

Qₚᵤₘₚ=kₚᵤₘₚ·nₚᵤₘₚ; (5)
in equation (5), Qₚᵤₘₚ represents the flow of the liquid pump; kₚᵤₘₚ represents the gain of the liquid pump; and nₚᵤₘₚ represents the rotational speed of the liquid pump.

The flow of the liquid pump refers to the volume of a chemical liquid transported by the liquid pump per unit time. In some embodiments, the flow of the liquid pump may be measured by a flow sensor mounted at an outlet of the liquid pump, or may be calculated and determined based on the rotational speed of the rotational speed and a performance curve of the liquid pump. In some embodiments, the rotational speed of the liquid pump may be determined by feedback signals from a motor encoder, a Hall sensor, or a motor driver of the liquid pump.

The gain kₚᵤₘₚ of the liquid pump is a comprehensive coefficient that characterizes the displacement and transmission efficiency of the liquid pump. In some embodiments, the coefficient of the liquid pump is obtained by offline experimental calibration, i.e., by measuring output flows corresponding to different rotational speeds at a standard pressure, and performing linear fitting to obtain an initial slope. In some embodiments, in an initial start-up stage of the spraying control system, a manually preset nominal initial value is used as the gain kₚᵤₘₚ of the liquid pump. In an operation process, the lower-computer controller dynamically updates the value of kₚᵤₘₚ online using a parameter identification algorithm shown in equation (13) (such as recursive least squares or an incremental compensation algorithm) based on real-time feedback data from the flow sensor, to compensate for flow fluctuations caused by changes in back pressure of the system, pump wear, or differences in the chemical liquid viscosity, and ensure high reliability of the control model.

A nonlinear relationship between a flow of an electric valve recirculated water tank and the opening degree Vᵥₐₗᵥₑ of the electric ball valve and the pressure P_{supply} of the main pipeline is established as shown in equation (6):

Q_{recirculated}=kᵥₐₗᵥₑ·(Vᵥₐₗᵥₑ)^{α}·(P_{supply})^{β}; (6)

in equation (6), Q_{recirculated} represents the flow of the electric valve recirculated water tank; kᵥₐₗᵥₑ represents the gain of the electric ball valve; Vᵥₐₗᵥₑ represents the opening degree of the electric ball valve; P_{supply} is the pressure of the main pipeline; and α and β are nonlinear parameters, where α represents a nonlinear exponential parameter of the influence of the opening degree of the electric ball valve on the flow of the electric valve recirculated water tank, and β represents a nonlinear exponential parameter of the influence of the pressure of the main pipeline on the flow of the electric valve recirculated water tank.

In some embodiments, the nonlinear parameters α and β may be obtained by experimental calibration. During experimental calibration, the recirculated flow under different pressure gradients and opening gradients are recorded, and regression analysis is performed by nonlinear least squares to determine exponential values that matches the actual physical characteristics to the most extent.

The gain of the electric ball valve refers to a comprehensive coefficient that characterizes the through-flow capacity and opening response characteristics of the electric ball valve.

In some embodiments, in an initial start-up stage of the spraying control system, a manually preset nominal empirical value is used as the gain kᵥₐₗᵥₑ of the electric ball valve. In an operation process, the lower-computer controller performs real-time corrections to the kᵥₐₗᵥₑ by using an online identification algorithm as shown in equation (16), based on the difference (i.e., the actual recirculated flow) between an actual total flow monitored by the flow sensor and the flow consumed at a nozzle end. The gain update controlled based on actual operating conditions can effectively eliminate a residual between model prediction and the actual flow, and improve a response speed and a steady-state precision of pressure regulation of the main pipeline.

The flow of the electric valve recirculated water tank refers to the flow recirculated to the water tank through the electric ball valve. In some embodiments, the opening degree of the electric ball valve may be obtained via a position sensor embedded in the electric ball valve, such as an optical encoder, a potentiometer, or a Hall sensor. For a determination method of the pressure of the main pipeline, refer to relevant descriptions above.

A total flow of the main pipeline is the flow of the liquid pump minus the flow of the electric valve recirculated water tank, and is calculated by equation (7):

Qₜₒₜₐₗ=Qₚᵤₘₚ−Q_{recirculated}=kₚᵤₘₚ·nₚᵤₘₚ−kᵥₐₗᵥₑ·(Vᵥₐₗᵥₑ)^{α}·P_{supply})^{β} (7)
in equation (7), Qₜₒₜₐₗ is the total flow of the main pipeline; kₚᵤₘₚ represents the gain of the liquid pump; nₚᵤₘₚ represents the rotational speed of the liquid pump; kᵥₐₗᵥₑ represents the gain of the electric ball valve; Vᵥₐₗᵥₑ is the opening degree of the electric ball valve; and P_{supply} is the pressure of the main pipeline.

In some embodiments, Vᵥₐₗᵥₑ is obtained via a sensor or a control signal of the electric ball valve. In some embodiments, the pressure P_{supply} of the main pipeline is obtained via a pressure sensor. For a determination method of the rotational speed of the liquid pump, refer to relevant descriptions above.

In some embodiments, Qₜₒₜₐₗ is obtained via a flow sensor mounted on the main pipeline, and the total flow of the main pipeline may be calculated by the above equation (7) in a case that the main pipeline is not provided with a flow sensor.

### S2.2. Perform Calculation for Adaptive Control:

a flow error E_{Q} is shown in equation (8):

E_{Q}=Q_{required}−Qₜₒₜₐₗ (8)
in equation (8), E_{Q} represents the flow error; Q_{required} represents the required flow of the system; and Qₜₒₜₐₗ represents the total flow of the main pipeline.

In some embodiments, the required flow of the system may be preset by a user.

To enable the total flow of the main pipeline to track the required flow of the system, a flow error feedback term is introduced in a control process, so that the total flow of the main pipeline satisfies a relationship in equation (9):

Qₜₒₜₐₗ=Q_{required}+K_{feedback}E_{Q} (9)
in equation (9), K_{feedback} is a feedback coefficient.

The feedback coefficient refers to a coefficient that regulates the degree of influence of the flow error on the spraying control system. In some embodiments, the feedback coefficient may be user-defined.

By solving the rotational speed nₚᵤₘₚ of the liquid pump using equations (7) and (9), a control law of the rotational speed of the liquid pump may be obtained as shown in equation (10):

$${n}_{pump} = \frac{{Q}_{required} + {Q}_{recirculated} + {K}_{feedback} \cdot {E}_{Q}}{{k}_{pump}} \qquad ( 10 )$$

in equation (10), nₚᵤₘₚ represents the rotational speed of the liquid pump; Q_{required} represents the required flow of the system; Q_{recirculated} represents the flow of the electric valve recirculated water tank; and K_{feedback} is the feedback coefficient.

In some embodiments, to enable the total flow of the main pipeline to track the required flow of the system, the K_{feedback} may take a value of −1, and the total flow of the main pipeline satisfies a relationship in the following equation (11):

Qₜₒₜₐₗ=Q_{required}−E_{Q} (11)

By solving the rotational speed nₚᵤₘₚ of the liquid pump using equations (7) and (11), a control law of the rotational speed of the liquid pump may be obtained as shown in equation (12):

$${n}_{pump} = \frac{{Q}_{required} + {Q}_{recirculated} - {E}_{Q}}{{k}_{pump}} \qquad ( 12 )$$

in equation (12), nₚᵤₘₚ represents the rotational speed of the liquid pump; Q_{required} represents the required flow of the system; and Q_{recirculated} represents the flow of the electric valve recirculated water tank.

To enable the total flow of the main pipeline to track the required flow of the system, i.e., control the target as Qₜₒₜₐₗ=Q_{required}, the equation (7) is substituted to solve the Vᵥₐₗᵥₑ to obtain a basic control law of the opening degree of the electric ball valve as shown in equation (13):

$${V}_{valve , base} = {( \frac{{k}_{pump} \cdot {n}_{pump} - {Q}_{required}}{{k}_{valve} \cdot {( {P}_{supply} )}^{β}} )}^{1 / α} \qquad ( 13 )$$

in equation (13), Vᵥₐₗᵥₑ, base is the basic control law of the opening degree of the electric ball valve.

To improve a robustness of the spraying control system under dynamic response of the liquid pump, pressure fluctuations in a pipeline, and external disturbances, a robust feedback term needs to be introduced into control of the opening degree of the electric ball valve, i.e., based on the basic control law of the opening degree, the robust feedback term −K_{robust}·(E_{Q}+λĖ_{Q}) is introduced to obtain a control law of the opening degree of the electric ball valve as shown in equation (14):

$${V}_{valve} = {( \frac{- {Q}_{required} + {k}_{pump} \cdot {n}_{pump}}{{k}_{valve} \cdot {( {P}_{supply} )}^{β}} )}^{1 / α} - {K}_{robust} \cdot ( {E}_{Q} + λ \cdot {\dot{E}}_{Q} ) \qquad ( 14 )$$

in equation (14), K_{robust} is a robust gain, the robust gain being user-defined in some embodiments; A is a constant for adjusting a feedback rate, Ė_{Q} is a time derivative of the flow error, and robust feedback is added to optimize control of the opening degree of the electric valve. Specifically, for control of the opening degree of the electric valve, not only model compensation (adaptive control of a gain) needs to be considered, but also the control input needs to be adjusted based on the flow error and the error change, to enhance the stability and robustness of the spraying control system.

### S2.3. Control Gain Update:

to enable adaptive adjustment of the gains kᵥₐₗᵥₑ and kₚᵤₘₚ and unknown nonlinear parameters α and β, an error-based online update algorithm is designed, and the specific gain update is as follows:

### (1) Gain Update of the Liquid Pump is as Shown in Equation (15):

[symbol] (t+1)= [symbol] (t)+γ₁·E_{Q}·nₚᵤₘₚ (15)
in equation (15), [symbol] (t) represents the gain of the liquid pump at time t; [symbol] (t+1) represents the gain of the liquid pump updated at time t+1; E_{Q} represents the flow error; and nₚᵤₘₚ represents the rotational speed of the liquid pump. In some embodiments, the flow error may be calculated by the equation (8).

### (2) Gain Update of the Electric Ball Valve is as Shown in Equation (16):

[symbol] (t+1)= [symbol] (t)+γ₂·E_{Q}·Vᵥₐₗᵥₑ; (16)
in equation (16), [symbol] (t) represents the gain of the electric ball valve at time t; [symbol] (t+1) represents the gain of the electric ball valve updated at time t+1; E_{Q} represents the flow error; and Vᵥₐₗᵥₑ represents the opening degree of the electric ball valve.

### (3) Update of an Adaptive Parameter is as Shown in Equations (17) and (18):

for α and β, the values thereof are dynamically adjusted by controlling the error and feedback of the flow, and the sensitivity of the total flow Qₜₒₜₐₗ of the main pipeline based on α and β is as follows:

$$\hat{α} ( t + 1 ) = \hat{α} ( t ) + {γ}_{3} \cdot {E}_{Q} \cdot \frac{\partial {Q}_{total}}{\partial α} ; \qquad ( 17 )$$

$$\hat{β} ( t + 1 ) = \hat{β} ( t ) + {γ}_{4} \cdot {E}_{Q} \cdot \frac{\partial {Q}_{total}}{\partial β} ; \qquad ( 18 )$$

in equations (17) and (18), \hat{α}(t) represents α at time t; \hat{α}(t+1) represents α updated at time t+1; \hat{β}(t) represents β at the time t; \hat{β}(t+1) represents β updated at the time t+1; and E_{Q} represents the flow error. In some embodiments, kᵥₐₗᵥₑ, kₚᵤₘₚ, α, and β are updated in real time as time-varying gains, the initial values thereof may be preset by those skilled in the art based on experience, and the gains are adaptively updated based on the above equations (15) to (18) during operation of the spraying control system.

In equations (17) and (18),

$$\frac{\partial {Q}_{total}}{\partial α} and \frac{\partial {Q}_{total}}{\partial β}$$

are sensitivity coefficients with respect to α and β, and are calculated by the following equations (19) and (20):

$$\frac{\partial {Q}_{total}}{\partial α} = - {k}_{v a l v e} \cdot {( {V}_{v a l v e} )}^{α} \cdot {( {P}_{supply} )}^{β} \cdot ln ( {V}_{valve} ) ; \qquad ( 19 )$$

$$\frac{\partial {Q}_{total}}{\partial β} = - {k}_{v a l v e} \cdot {( {V}_{v a l v e} )}^{α} \cdot {( {P}_{supply} )}^{β} \cdot ln ( {P}_{supply} ) ; \qquad ( 20 )$$

in equations (15) to (20), γ₁, γ₂, γ₃ and γ₄ are adaptive gains for adjusting a learning rate.

In some embodiments, via the adaptive updates by S2.1 to S2.3, the control law of the opening degree of the electric valve updates the gain parameters in real time, namely, the gain kₚᵤₘₚ of the liquid pump, the gain kᵥₐₗᵥₑ of the electric ball valve, and the unknown nonlinear parameters α and β can all be adjusted in real time based on the control error, thereby achieving precise flow control. By introducing a robust feedback term, the spraying control system can better deal with external perturbations, uncertainties of system parameters, and model errors, thereby enhancing the robustness and stability of the spraying control system.

In some embodiments, in S3, in image analysis and data processing, calculation for control is performed for two input cases: a prescription map-based decision system and a vision-based decision system for precision spot spraying. In the processes of prescription map-based spraying and vision-based precision spot spraying, the target flows of each nozzle may be adjusted based on the different input cases, specifically by the following S3.1 to S3.5:

### S3.1. Set the Target Flow of Each Nozzle:

Prescription map-based spraying: Based on the latitude and longitude position (xᵢ, yᵢ) of the i^{th} nozzle, the target flow Q_{nozzle,i,target1} of each nozzle is obtained by analyzing a prescription map provided by the prescription map-based decision system. To obtain the latitude and longitude position (xᵢ, yᵢ) of the i^{th} nozzle, a high-precision positioning system (e.g., a dual antenna RTK-GNSS) may provide the real-time coordinates and azimuth of an agricultural robot. Then, based on preset mechanical topological parameters (i.e., lateral and longitudinal offsets of the nozzles relative to a GPS antenna), the lower-computer controller uses a rigid body kinematics model to resolve the instantaneous geographic coordinates of each nozzle in the array, thereby obtaining the latitude and longitude position (xᵢ, yᵢ) of the i^{th} nozzle. In some embodiments, the target flow of the i^{th} nozzle is shown in equation (21):

Q_{nozzle,i,target1}=ƒ_{prescription}(xᵢ,yᵢ) (21)
in equation (21), ƒ_{prescription}( ) represents a prescription map analyzing function; xᵢ represents the longitude of the i^{th} nozzle; yᵢ represents the latitude of the i^{th} nozzle; and Q_{nozzle,i,target1} represents the target flow of the i^{th} nozzle obtained by analyzing of the prescription map-based spraying.

In some embodiments, the prescription map analyzing function can analyze the target flow corresponding to a current position from the input prescription map data based on the current latitude and longitude coordinates of a nozzle. The analyzing process may be implemented using a spatial data interpolation algorithm, such as a nearest neighbor method and a bilinear interpolation method. In some embodiments, the prescription map analyzing function maps discrete geographic coordinates of the nozzle to a grid or vector region defined by the prescription map. In some embodiments, when the nozzle is located at a boundary of volume defined by the prescription map, the spraying control system implements smooth transition of the spraying quantity by using a bilinear interpolation algorithm, to avoid frequent and severe fluctuations of an actuator caused by positioning jitter.

The prescription map-based decision system (also known as a prescription map output system) refers to a system that provides prescription map input to a spraying system. The prescription map refers to pre-designed data containing information on the spraying quantity in each region, and is used to guide each nozzle to perform spraying at a predetermined volume in different regions. The prescription map-based spraying refers to a spraying mode of the spraying control system that performs spraying in each region according to the predetermined spraying quantity based on the prescription map provided by the prescription map-based decision system.

Vision-based precision spot spraying: Based on the crop density and a three-dimensional structure (ρᵢ, hᵢ) identified by the vision-based decision system for precision spot spraying, the target flow Q_{nozzle,i,target2} of each nozzle is calculated, i.e., the target flow of the i^{th} nozzle is as shown in equation (22):

Q_{nozzle,i,target2}=gᵥᵢₛᵤₐₗ(ρᵢ,hᵢ); (22)

in equation (22), gᵥᵢₛᵤₐₗ( ) represents a vision-based resolution function; ρᵢ represents the crop density within a region of a field of view covered by the i^{th} nozzle; hᵢ represents a three-dimensional structure of crops within the region of the field of view covered by the i^{th} nozzle; and Q_{nozzle,i,target2} represents the target flow of the i^{th} nozzle obtained by analyzing of the vision-based precision spot spraying.

The vision-based resolution function refers to a function that analyzes a target flow corresponding to the crop density and the three-dimensional structure identified by the vision-based decision system for precision spot spraying.

In some embodiments, the vision-based resolution function gᵥᵢₛᵤₐₗ(⋅) may use a hierarchical matching strategy or a linear mapping model. For example, when a three-dimensional structure of crops is identified as exceeding a preset threshold, the vision-based resolution function linearly increases the target flow. In some embodiments, the vision-based resolution function may use a pre-trained deep neural network or a lookup table to adaptively correct parameters based on environmental lighting and crop types.

The crop density refers to the number of crops per unit area. In some embodiments, the crop density may be obtained by performing threshold segmentation or segmentation using a semantic segmentation model (e.g., UNet) by means of excess green index (ExG) extraction, color space conversion (e.g., from RGB to Lab space), and a maximum between-class variance method.

In some embodiments, the three-dimensional structure may be obtained through binocular vision-based matching, structured light ranging, or monocular vision-based structure from motion (SfM) algorithms. In some embodiments, the crop height may be calculated by geometric back projection by means of the mounting height of a camera and a projected position of crop canopies in an image. The canopy volume may be obtained by integrating the connected domain size and depth information of the segmented target regions.

The vision-based decision system for precision spot spraying refers to an intelligent perception identification system that uses photoelectric imaging devices (e.g., a monocular/binocular camera and a multispectral camera) to collect images of an operating region, and integrates an AI edge computing platform to identify and locate targets (e.g., crops or weeds) in real time by target detection, semantic segmentation, or feature extraction algorithms. The vision-based precision spot spraying refers to a spraying mode in which the spraying control system receives target geometric features, biomass information, and relative spatial poses fed back by the vision-based decision system for precision spot spraying in real time, and combined with the real-time motion state of an agricultural robot, dynamically resolves and adjusts the target flow of each independent nozzle in a nozzle array.

In some embodiments of this specification, a vision-based precision spot spraying process achieves an on-demand precise spraying mode of “spraying when a target appears and stopping spraying in a region without a target” by precisely scheduling the timing of each execution end.

### S3.2. Calculate the Real-Time Flow Error of Each Nozzle:

For each nozzle, the real-time flow error is calculated as shown in equation (23):

ΔQᵢ=Q_{nozzle,i,target}−Q_{nozzle,i,actual} (23)
in equation (23), ΔQᵢ represents the real-time flow error of the i^{th} nozzle; Q_{nozzle,i,target} represents the target flow of the i^{th} nozzle; and Q_{nozzle,i,actual} represents the actual flow of the i^{th} nozzle.

In some embodiments, Q_{nozzle,i,target} may be obtained based on the input of the prescription map-based decision system or the vision-based decision system for precision spot spraying. When the input is the input of the prescription map-based decision system, the value of Q_{nozzle,i,target} may be calculated as Q_{nozzle,i,target1} by the equation (21). When the input is the input of the vision-based decision system for precision spot spraying, the value of Q_{nozzle,i,target} may be calculated as Q_{nozzle,i,target2} by the equation (22).

In some embodiments, Q_{nozzle,i,actual} may be calculated via the pressure of the main pipeline and the duty ratio, or be directly measured by the flow sensor.

### S3.3. Adjust and Calculate the Duty Ratio for Each Nozzle:

In some embodiments, the duty ratio of a PWM proportional electromagnetic valve corresponding to a nozzle is adjusted via adaptive control based on the real-time flow error and the target flow as shown in equation (24):

$${D}_{i , n e w} = {D}_{i , old} + {K}_{p , i} \cdot Δ {Q}_{i} \cdot \sqrt{\frac{{P}_{supply , i}}{{P}_{s e t}}} \qquad ( 24 )$$

in equation (24), D_{i,new} represents the duty ratio of the PWM proportional electromagnetic valve on a nozzle branch where the i^{th} nozzle is located, the duty ratio being updated based on the real-time flow error and the target flow; and D_{i,old} represents the duty ratio actually executed by the PWM proportional electromagnetic valve on the nozzle branch where the i^{th} nozzle is located in the previous control cycle. ΔQᵢ is the real-time flow error of the i^{th} nozzle; K_{p,i} (also represented as Kₚ) is an adaptive gain, representing an adaptive gain of the i^{th} nozzle; P_{supply,i} is the real-time pressure measured by a pressure sensor, representing the actual pressure at the i^{th} nozzle; and Pₛₑₜ is a set pressure. In some embodiments, the set pressure is preset by a user.

In some embodiments, the duty ratio of a PWM proportional electromagnetic valve corresponding to a nozzle is adjusted via adaptive control based on the real-time flow error and the target flow as shown in equation (25):

$${D}_{i , new} = {D}_{i , old} + {K}_{p , i} \cdot Δ {Q}_{i} \cdot \sqrt{\frac{{P}_{supply}}{{P}_{set}}} \qquad ( 25 )$$

in equation (25), D_{i,new} represents the duty ratio of the PWM proportional electromagnetic valve on the nozzle branch where the i^{th} nozzle is located, the duty ratio being updated based on the real-time flow error and the target flow; and D_{i,old} represents the duty ratio actually executed by the PWM proportional electromagnetic valve on the nozzle branch where the i^{th} nozzle is located in the previous control cycle. ΔQᵢ is the real-time flow error; K_{p,i}, is an adaptive gain; P_{supply} is the pressure of the main pipeline; and Pₛₑₜ is the set pressure.

In some embodiments of this specification, by equations (24) and (25), incremental adjustment is performed based on the duty ratio of the PWM proportional electromagnetic valve on the nozzle branch where the i^{th} nozzle is located in the previous control cycle, thereby ensuring the continuity and stability of control.

To deal with a dynamically changing environment and system uncertainties, a compensation term based on pressure feedback is added and enhanced with robustness control, and the adjusted duty ratio is as shown in equation (26):

$${D}_{i , new}^{′} = {D}_{i , new} \cdot ( 1 + {K}_{robust} \cdot \frac{Δ {Q}_{i}}{{Q}_{nozzle , i , target}} ) \qquad ( 26 )$$

in equation (26), K_{robust} is a robust gain, allowing the controller to be more adaptive to perturbations and parameter uncertainties. The value of the robust gain may be user-defined. The D_{i,new} on the right side of the equal sign in the equation (26) represents the duty ratio updated based on the real-time flow error and the target flow calculated by the equation (24) or (25), while the

$${D}_{i , new}^{′}$$

on the left side of the equal sign represents the updated duty ratio enhanced by adding the pressure feedback compensation term and the robust gain.

### S3.4. Automatically Adjust a Gain Parameter:

The gain K_{p,i,new} is updated based on the flow error ΔPᵢ and the pressure error K_{p,i,new} as shown in equation (27):

K_{p,i,new}=K_{p,i,old}+μ_{p,i}·(ΔQᵢ·ΔPᵢ) (27)
in equation (24), K_{p,i,new} is the updated gain parameter of the i^{th} nozzle; K_{p,i,old} is the gain parameter of the i^{th} nozzle before updating; μ_{p,i} is a learning rate for gain adjustment of the i^{th} nozzle, used to control the size of an update step, ensure smooth updates and avoid system instability; ΔQᵢ=Q_{nozzle,i,target}−Q_{nozzle,i,actual} is the real-time flow error of the i^{th} nozzle, which is the difference between the target flow Q_{nozzle,i,target} (also represented as Q_{target,i}) and the actual flow Q_{nozzle,i,actual} (also represented as Q_{actual,i}), and thus the real-time flow error of the i^{th} nozzle is also represented as: ΔQᵢ=Q_{target,i}−Q_{actual,i}; and ΔPᵢ is the pressure error of the i^{th} nozzle, which may be determined by the difference between the set pressure Pₛₑₜ and the real-time pressure P_{supply,i}, i.e. ΔPᵢ=Pₛₑₜ−P_{supply,i}. The real-time pressure P_{supply,i} refers to the actual pressure at the i^{th} nozzle.

In some embodiments, the learning rate μ_{p,i} for gain adjustment is adjusted based on a system response. Typically, a relatively small learning rate may reduce system shock, and a relatively large learning rate may accelerate convergence. The learning rate is adjusted as shown in the following equation (28):

$${μ}_{p , i} = \frac{{μ}_{0 , i}}{1 + {α}_{i} \cdot ( Δ {Q}_{i}^{2} + Δ {P}_{i}^{2} )} \qquad ( 28 )$$

in equation (28), μ_{p,i} is the learning rate for gain adjustment of the i^{th} nozzle, which may be adjusted based on the system response and an initial learning rate; μ_{0,i} is the initial learning rate of the i^{th} nozzle; ai is a learning rate decay coefficient, used to adjust the learning rate based on the flow and the pressure error; and ΔQᵢ and ΔPᵢ are the real-time flow error and pressure error of the i^{th} nozzle respectively. In some embodiments, μ_{0,i} may be manually preset.

In some embodiments of this specification, by dynamically adjusting the learning rate with the equation (28), updating of a gain is more flexible, and when the real-time flow error and pressure error are large, an update step is automatically increased to increase the response speed of the controller.

### S3.5. Calculate the Updated Gain:

The gain K_{p,i,new} for each nozzle is calculated as in the following equation (29):

$${K}_{p , i , new} = {K}_{p , i , old} + \frac{{μ}_{0 , i}}{1 + {α}_{i} \cdot ( Δ {Q}_{i}^{2} + Δ {P}_{i}^{2} )} \cdot ( Δ {Q}_{i} \cdot Δ {P}_{i} ) ; \qquad ( 29 )$$

In some embodiments, the gain K_{p,i,new} calculated with the equation (29) is substituted into the equation (24) of the above controller to obtain the duty ratio signal of the PWM proportional electromagnetic valve corresponding to each nozzle as shown in equations (30) and (31):

$${D}_{i , new 1} = {D}_{i , old} + {K}_{p , i , new} \cdot Δ {Q}_{i} \cdot \sqrt{\frac{{P}_{supply , i}}{{P}_{set}}} \qquad ( 30 )$$

$${D}_{i , new 1}^{′} = {D}_{i , new 1} \cdot ( 1 + {K}_{robust} \cdot \frac{Δ {Q}_{i}}{{Q}_{nozzle , i , target}} ) \qquad ( 31 )$$

in equations (30) and (31), D_{i,new1} represents a target duty ratio instruction of the PWM proportional electromagnetic valve on the nozzle branch where the i^{th} nozzle is located in a current control cycle after gain correction, the value of the target duty ratio command being a predicted value calculated based on the deviation between the previous state and the current flow; and D_{i,old} represents the duty ratio actually executed by the PWM proportional electromagnetic valve on the nozzle branch where the i^{th} nozzle is located in the previous control cycle.

$${D}_{i , new 1}^{′}$$

represents an executing duty ratio signal finally outputted by the i^{th} nozzle to the PWM electromagnetic valve, the value of the executing duty ratio signal being further calibrated by a robust algorithm based on D_{i,new1} and being a control variable that directly drives hardware. In some embodiments, the calculated gain K_{p,i,new} is substituted into the equation (25) of the above controller to obtain the duty ratio signal of the PWM proportional electromagnetic valve corresponding to each nozzle as shown in equations (32) and (33):

$${D}_{i , new 1} = {D}_{i , old} + {K}_{p , i , new} \cdot Δ {Q}_{i} \cdot \sqrt{\frac{{P}_{supply}}{{P}_{set}}} \qquad ( 32 )$$

$${D}_{i , new 1}^{′} = {D}_{i , new 1} \cdot ( 1 + {K}_{robust} \cdot \frac{Δ {Q}_{i}}{{Q}_{nozzle , i , target}} ) \qquad ( 33 )$$

in equations (32) and (33), D_{i,new1} represents a target duty ratio instruction of the PWM proportional electromagnetic valve on the nozzle branch where the i^{th} nozzle is located in a current control cycle after gain correction, the value of the target duty ratio command being a predicted value calculated based on the deviation between the previous state and the current flow; and D_{i,old} represents the duty ratio actually executed by the PWM proportional electromagnetic valve on the nozzle branch where the i^{th} nozzle is located in the previous control cycle.

$${D}_{i , new 1}^{′}$$

represents an executing duty ratio signal finally outputted by the i^{th} nozzle to the PWM electromagnetic valve, the value of the executing duty ratio signal being further calibrated by a robust algorithm based on D_{i,new1} and being a control variable that directly drives hardware. P_{supply} represents the pressure of the main pipeline.

In some embodiments of this specification, by S3.1 to S3.5, the difference between the target flow and the actual flow of each nozzle is adjusted, and the duty ratio is adjusted by using an adaptive gain, to ensure that the flow of the nozzle is precisely controlled in different spraying scenarios and precise spraying is achieved. The actual flow of each nozzle is adjusted via the duty ratio of the PWM proportional electromagnetic valve, and both the flow and the pressure are controlled with reference to the pressure feedback.

In some embodiments, in S3, for control of spraying when both the prescription map-based spraying and the vision-based precision spot spraying are not applicable, calculation is performed based on nozzle pressure compensation and local gain adjustment, specifically by S3.6 to S3.8 as follows:

### S3.6. Feed the Nozzle Pressure Back:

The pressure difference of each nozzle may cause different flows, thus for each nozzle, the duty ratio is corrected via local pressure feedback, and the spray pressure (also known as pressure difference) of each nozzle is represented by P_{nozzle,i}, and is measured in real time by the pressure sensor at the nozzle. The corrected duty ratio for each nozzle is dynamically adjusted based on the spray pressure thereof.

A global gain K_{i,global} (also represented as K_{global}) is introduced to adjust a control output of each nozzle to ensure that the flow of the entire system meets a target requirement, and is achieved by weighting based on the local duty ratio as in the following equation (34):

$${D}_{i , new 2} = {D}_{i , old 1} \cdot ( \sqrt{\frac{{P}_{nozzle , i}}{{P}_{set}}} ) \cdot {K}_{i , global} ; \qquad ( 34 )$$

in equation (34), D_{i,new2} represents the duty ratio of the PWM proportional electromagnetic valve on the nozzle branch where the i^{th} nozzle is located after global gain update; D_{i,old1} represents a reference duty ratio of the PWM proportional electromagnetic valve on the nozzle branch where the i^{th} nozzle is located before correction in the current control cycle; K_{i,global} represents a global gain; and P_{nozzle,i} represents the spray pressure of the i^{th} nozzle.

### S3.7. Perform Calculation for Adaptive Control:

Considering that in actual operations, the nozzle pressure may change and the pressure difference in the nozzles may be large, the global gain K_{global} is dynamically adjusted by a neural network adaptive algorithm to better deal with complex and changing working conditions. The global gain K_{i,global} is predicted by introducing a neural network model, and the gain is automatically adjusted based on the real-time flow error and pressure feedback, and a gain update equation is shown as the following equation (35):

K_{i,global}(t+1)=K_{i,global}(t)−α−∇J(K_{i,global}); (35)
in equation (35), K_{i,global}(t) (also represented as K_{global}(t)) is the current value of the global gain; a is a learning rate; ∇J(K_{i,global}) (also represented as ∇J(K_{global})) is a gradient of a loss function with respect to the gain; and K_{i,global}(t+1) (also represented as K_{global}(t+1)) is the updated global gain.

In some embodiments, the spraying control system implements dynamic adaptive adjustment of the nozzle gain by using a neural network model. The neural network model refers to a deep learning model that performs gain feature identification and parameter optimization based on multi-source measured perception data, for example, a long short term memory (LSTM) network model, a time convolutional network (TCN) model, or a combination thereof, with an aim of capturing a nonlinear law of a chemical liquid flow in complex pipelines by a temporal processing ability.

In some embodiments, the input of the neural network model is multidimensional real-time operating data of the nozzles in a preset time period, including but not limited to: pressure data measured by the main pipeline and the nozzle branches, flow data measured by the main pipeline and the nozzle branches, the real-time duty ratios of the PWM electromagnetic valves of the nozzles, and the target flows of the nozzles. An output of the neural network model is a gain correction vector corresponding to the nozzles. The gain correction vector reflects a gain adjustment amount required to achieve the target flow under the currently measured pressure distribution and flow deviation, thereby achieving precise characterization of control characteristics of independent execution channels.

In some embodiments, an initial neural network model is trained by using a plurality of sets of first training samples with a first label. The first training samples include operating sequence data (including the pressures, flows, and duty ratios of the main pipeline and the branches) of a sample nozzle within a preset time period in historical operation data. The first label is an optimal gain correction resolved based on the values measured by branch sensors in the corresponding time period. The lower-computer control system or the AI edge computing platform can obtain a neural network model that can precisely map a “measured operating condition and ideal gain” relationship by constructing a loss function and iteratively updating the model parameters using gradient descent and other algorithms until the loss function converges or a preset number of iterations is reached. In practical operations, the spraying control system directly inputs the pressure deviation and the flow error measured by the sensors into the neural network model, and obtains gain update values in real time, thereby ensuring that the system still has extremely high precision and robustness for spraying in complex and fluctuating pressure environments.

In some embodiments, the loss function J may be a square of the flow error as shown in equation (36):

$$J ( {K}_{i , global} ) = {\sum }_{i = 1}^{N} {( {Q}_{nozzle , i , target} - {Q}_{nozzle , i , actual} )}^{2} \qquad ( 36 )$$

in equation (36), J(K_{i,global}) (also represented as J(K_{global})) represents the loss function; Q_{nozzle,i,target} (also represented as Q_{nozzle,target}) is the target flow of the i^{th} nozzle; and Q_{nozzle,i,actual} (also represented as Q_{nozzle,actual}) is the actual flow of the i^{th} nozzle, which may be measured by a flow sensor.

In some embodiments, to achieve consistent atomization characteristics (e.g., the size and the coverage uniformity of fog droplets) across an overall breadth range while achieving variable spraying precisions of the nozzles, the loss function in the neural network training phase may be a composite loss function incorporating flow and pressure as shown in equation (37):

$$( 37 )$$

$$J ( {K}_{i , global} ) = {\sum }_{i = 1}^{N} {( {Q}_{nozzle , i , target} - {Q}_{nozzle , i , actual} )}^{2} + λ {\sum }_{i = 1}^{N} {( {P}_{i , actual} - \overline{P} )}^{2}$$

in equation (37), J(K_{i,global}) represents the loss function; and Q_{nozzle,i,target}−Q_{nozzle,i,actual} is a residual between a value measured by the flow sensor of the i^{th} nozzle branch and the target flow, which aims to drive the model to achieve absolute precision in the spraying quantity. P_{i,actual} is a real-time monitored value of the pressure sensor at the i^{th} nozzle, and P̅ is an average pressure at all nozzles on the spray boom.

$${\sum }_{i = 1}^{N} {( {P}_{i , actual} - \overline{P} )}^{2}$$

aims to minimize a pressure gradient at each execution end caused by linear loss of a pipeline. A weight factor A is used to balance a priority between the flow precision and pressure smoothness, which can be set based on experience.

In some embodiments, the lower-computer control system (or the AI edge computer) uses a “multi-source measured data set” accumulated in historical operations to iteratively optimize the neural network model (e.g., LSTM or TCN). The input of the neural network model includes the pressure/flow of the main pipeline, the measured pressure/flow of the branches, and a PWM duty ratio sequence within a preset period. By a backpropagation algorithm, the model aims at minimizing the composite loss function J(K_{i,global}) and deeply learns nonlinear gain characteristics of the branches under different pressure distributions.

In an actual operating process, the trained neural network model dynamically outputs the optimal gain corrections for the nozzles based on the pressure deviations and flow errors of the branches collected in real time. The spraying control system no longer relies on fixed empirical equations, but uses the neural network to provide real-time response to the current J(K_{i,global}) value and resolve a gain coefficient K_{i,global} that can simultaneously correct the flow deviation and maintain pressure stability. The updated gain is substituted into a duty ratio reconstruction equation. For example, when it is detected that the flow of a nozzle at the end of the spray boom is insufficient due to physical pressure drop, the system compensates for the duty ratio of the branch first by the adaptive gain within an allowable range of global pressure, and ensures that the adjustment cannot cause pressure oscillations of the entire system, thereby achieving precise full-breadth spraying with high robustness.

S3.8. An equation for comprehensive control of the flow and pressure stabilization of a nozzle is as shown in the following equation (38):

$${D}_{i , new 3} = {D}_{i , old} + ( {Q}_{nozzle , i , target} - {Q}_{nozzle , i , tactual} ) \cdot \sqrt{\frac{{P}_{set}}{{P}_{nozzle , i}}} \cdot {K}_{i , global}^{′} \qquad ( 38 )$$

in equation (38), D_{i,new3} represents the target duty ratio of the PWM proportional electromagnetic valve on the nozzle branch where the i^{th} nozzle is located in the current control cycle, the target duty ratio being updated by an adaptive proportional gain identified and updated in real time by the neural network model; D_{i,old} represents the duty ratio actually executed by the PWM proportional electromagnetic valve on the nozzle branch where the i^{th} nozzle is located in the previous control cycle; and

$${K}_{i , global}^{′}$$

represents an adaptive proportional gain identified and updated in real time by the neural network model, which reflects flow response characteristics of the i^{th} nozzle under a current wear state and chemical liquid viscosity, and can be calculated by the equation (35). Q_{nozzle,i,target}−Q_{nozzle,i,tactual} represents the flow error of the i^{th} nozzle. Q_{nozzle,i,tactual} is an actual feedback value measured by the flow sensor mounted on the nozzle branch. Pₛₑₜ is a preset pressure, and P_{nozzle,i} is the real-time pressure of the nozzle branch measured by the pressure sensor at the nozzle, which, by means of square root proportional adjustment, dynamically compensates for disturbance caused by fluctuations of pipeline pressure drop on the flow.

In some embodiments, an equation for comprehensive control of the flow and pressure stabilization of a nozzle is as shown in the following equation (39):

$${D}_{i , new 3} = {D}_{i , old} + {K}_{p , i} \cdot N \cdot ( {Q}_{nozzle , i , target} - {Q}_{nozzle , i , tactual} ) \cdot \sqrt{\frac{{P}_{set}}{{P}_{nozzle , i}}} \cdot {K}_{i , global}^{′} \qquad ( 39 )$$

in equation (39), D_{i,new3} represents the target duty ratio of the PWM proportional electromagnetic valve on the nozzle branch where the i^{th} nozzle is located in the current control cycle, the target duty ratio being updated by an adaptive proportional gain identified and updated in real time by the neural network model; D_{i,old} represents the duty ratio actually executed by the PWM proportional electromagnetic valve on the nozzle branch where the i^{th} nozzle is located in the previous control cycle; and

$${K}_{i , global}^{′}$$

represents an adaptive proportional gain identified and updated in real time by the neural network model, which reflects flow response characteristics of the i^{th} nozzle under a current wear state and chemical liquid viscosity, and can be calculated by the equation (35). Q_{nozzle,i,target}−Q_{nozzle,i,tactual} represents the flow error of the i^{th} nozzle. Q_{nozzle,i,tactual} is an actual feedback value measured by the flow sensor mounted on the nozzle branch. Pₛₑₜ is a preset pressure, and P_{nozzle,i} is the real-time pressure of the nozzle branch measured by the pressure sensor at the nozzle, which, by means of square root proportional adjustment, dynamically compensates for disturbance caused by fluctuations of pipeline pressure drop on the flow. N is a flow coefficient, which represents the maximum flow value of the nozzle corresponding to the maximum duty ratio instruction signal of the PWM electromagnetic valve.

In some embodiments of this specification, when both the prescription map-based spraying and the vision-based precision spot spraying are not applicable, an algorithm based on nozzle pressure compensation and local gain adjustment is designed considering the difference in pressure of each nozzle as shown in equations (34) to (39), to make control of each nozzle more precise.

In some embodiments of this specification, the duty ratio is adjusted via the real-time flow error to ensure that the nozzle flow approaches a target flow; closed-loop control of the flow is performed; the duty ratio is dynamically adjusted based on the real-time pressure feedback of each nozzle to compensate for a pressure difference and optimize the spraying effect of the nozzle; and online gain adjustment is performed by using the adaptive algorithm to improve the adaptability and robustness of the system.

Preferred specific implementations of the present disclosure are described above in detail with reference to the accompanying drawings. However, the present disclosure is not limited to specific details in the above specific implementations. Various equivalent variations may be made to the technical solutions of the present disclosure within the scope of the technical idea of the present disclosure, and all such equivalent variations fall within the protection scope of the present disclosure.

Basic concepts have been described above. Obviously, for those skilled in the art, the detailed disclosure above is only an example and does not constitute a limitation on this specification. Although not explicitly stated here, those skilled in the art may make various modifications, improvements, and revisions to this specification. Such modifications, improvements, and revisions are suggested in this specification, so they still fall within the spirit and scope of the exemplary embodiments in this specification.

In addition, specific words are used in this specification to describe the embodiments of this specification. For example, “one embodiment”, “an embodiment”, and/or “some embodiments” refer to a certain feature, structure, or characteristic related to at least one embodiment of this specification. Therefore, it should be emphasized and noted that the “an embodiment” or “one embodiment” or “an alternative embodiment” mentioned twice or more in different positions in this specification do not necessarily refer to the same embodiment. Moreover, certain features, structures, or characteristics in one or more embodiments of this specification may be appropriately combined.

In addition, unless explicitly stated in claims, the order for processing elements and sequences, the use of numbers and letters, or the use of other names in this specification are not intended to limit the order of the processes and methods described in this specification. Although the above disclosure discusses some embodiments of invention currently considered useful with various examples, it should be understood that such details are for illustrative purposes only, and the additional claims are not limited to the disclosed embodiments. On the contrary, the claims are intended to cover all modifications and equivalent combinations that comply with the essence and scope of the embodiments of this specification. For example, although system components described above can be implemented through hardware devices, they can also be implemented solely through software solutions. For example, the described system is mounted on an existing server or mobile device.

Similarly, it should be noted that to simplify the descriptions disclosed in this specification and assist in understanding one or more embodiments of the disclosure, the description of embodiments of this specification may sometimes integrate a plurality of features in one embodiment, drawing, or description therefor. However, such a disclosure method does not imply that a subject matter of this specification requires more features than those mentioned in the claims. In fact, the features of an embodiment are less than all the features of an individual embodiment disclosed above.

In some embodiments, numbers that describe the number of components and attributes are used. It should be understood that such numbers used for describing the embodiments are modified with modifiers such as “about,” “approximate,” or “generally” in some examples. Unless otherwise specified, the “about”, “approximate”, or “generally” indicates that the numbers allow for a variation of ±20%. Accordingly, in some embodiments, numerical parameters used in the specification and claims are all approximate values, which may vary depending on characteristics required by individual embodiments. In some embodiments, the numerical parameters should take into account a specified significant digit and use a general method for preserving digits. Although numerical domains and parameters used to confirm the extent of a range in some embodiments of this specification are approximate values, in specific embodiments, the setting of such numerical values is as accurate as possible within a feasible range.

For each patent, patent application, patent application publication, and other material referred to in this specification, such as an article, a book, a specification, a publication, and a document, the entire content thereof is hereby incorporated into this specification as a reference. Application history documents that are inconsistent or conflict with the content of this specification are excluded, and also documents that limit the widest scope of the claims of this specification (currently or subsequently attached to this specification) are excluded. It should be noted that if there is any inconsistency or conflict between the description, definition, and/or use of terms in the accompanying materials of this specification and the content described in this specification, the description, definition, and/or use of terms in this specification shall prevail.

Finally, it should be understood that the embodiments described in this specification are only intended to explain the principles of the embodiments of this specification. Other deformations may also fall within the scope of this specification. Therefore, as an example rather than a limitation, alternative configurations of the embodiments of this specification can be considered consistent with the teaching of this specification. Accordingly, the embodiments of this specification are not limited to the embodiments explicitly introduced and described in this specification.

What is claimed is:

1. A multi-input model-compensated spraying control method for agricultural robots, comprising the following steps:
S1. building a flow and pressure control model, the flow and pressure control model being constructed as follows:
1) building a nozzle flow model:
a nozzle flow Q_{nozzle} is controlled by both a duty ratio D of a PWM proportional electromagnetic valve and a pressure P_{supply} of a main pipeline, and is calculated as follows:
Q_{nozzle}=k_{Q}·D·\sqrt{P_{supply}};
where k_{Q} is a flow gain coefficient and is related to nozzle structural parameters; D is the duty ratio of the PWM proportional electromagnetic valve and is in a range of [0, 1]; and P_{supply} is the pressure of the main pipeline;
2) performing distribution of a required flow of a system and the nozzle flow:
without a prescription map-based decision system or a vision-based decision system for precision spot spraying, a fixed spraying quantity per mu is used, and the required flow Q_{required} of a system is determined by a unit area spraying quantity Q_{target}, a breadth W of a spray boom, and a vehicle speed v, and is calculated as follows:
Q_{required}=Q_{target}·W·v;
with the prescription map output system and the vision-based decision system for precision spot spraying, Q_{required} is equal to the sum of the target flows of all nozzles;
S2. controlling a liquid pump and an electric ball valve;
S3. controlling the nozzle flow and pressure stabilization with PWM; and
S4. based on a model-compensated multi-layer adaptive feedback control method, using the required flow of a system of the prescription map-based decision system and the vision-based decision system for precision spot spraying as control references, controlling a rotational speed of the liquid pump, an opening degree of the electric ball valve, and the duty ratio of the PWM proportional electromagnetic valve, adjusting the flow and the pressure by closed-loop feedback, to achieve pressure stabilization and flow control of each nozzle, and adjusting the flow and the pressure by closed-loop feedback, to ensure uniform and efficient spraying.

2. The multi-input model-compensated spraying control method for agricultural robots according to claim 1, wherein in S2, the controlling a liquid pump and an electric ball valve comprises:
1) modeling a spraying system:
a flow of the liquid pump and the rotational speed of the liquid pump have the following relationship:
Qₚᵤₘₚ=kₚᵤₘₚ·nₚᵤₘₚ
a nonlinear relationship between a flow of an electric valve recirculated water tank and the opening degree Vᵥₐₗᵥₑ of the electric ball valve and the pressure P_{supply} of the main pipeline is established:
Q_{recirculated}=kᵥₐₗᵥₑ·(Vᵥₐₗᵥₑ)^{α}·(P_{supply})^{β};
a total flow of the main pipeline is the flow of the liquid pump minus the flow of the electric valve recirculated water tank, and is calculated as:
Qₜₒₜₐₗ=kₚᵤₘₚ·nₚᵤₘₚ−kᵥₐₗᵥₑ·(Vᵥₐₗᵥₑ)^{α}·(P_{supply})^{β};
where the opening degree Vᵥₐₗᵥₑ of the electric ball valve is obtained via a sensor or a control signal of the electric ball valve, the pressure P_{supply} of the main pipeline is obtained via a pressure sensor, and Qₜₒₜₐₗ is obtained via a flow sensor mounted on the main pipeline, and the total flow of the main pipeline is calculated by the above equation without a flow sensor;
2) performing calculation for adaptive control:
a flow error E_{Q} is:
E_{Q}=Q_{required}−Qₜₒₜₐₗ
a control law of the rotational speed of the liquid pump is:
$${n}_{pump} = \frac{{Q}_{r e q u i r e d} + {Q}_{recirculated} + {K}_{feedback} \cdot {E}_{Q}}{{k}_{pump}}$$
K_{feedback} is a user-defined feedback coefficient;
a control law of the opening degree of the electric ball valve is:
$${V}_{valve} = {( \frac{{Q}_{required} + {k}_{pump} \cdot {n}_{pump}}{{k}_{valve} \cdot {( {P}_{supply} )}^{β}} )}^{1 / α} - {K}_{robust} \cdot ( {E}_{Q} + λ \cdot {\dot{E}}_{Q} ) ;$$
where K_{robust} is a robust gain, A is a constant for adjusting a feedback rate, Ė_{Q} is a time derivative of the flow error, and robust feedback is added to optimize control of the opening degree of the electric ball valve; and
3) controlling gain update:
to enable adaptive adjustment of the gains kᵥₐₗᵥₑ and kₚᵤₘₚ and unknown nonlinear parameters α and β, an error-based online update algorithm is designed, and the specific gain update is as follows:
(1) gain update of the liquid pump: [symbol]
(t+1)= [symbol] (t)+γ₁·E_{Q}·nₚᵤₘₚ;
(2) gain update of the electric ball valve: [symbol]
(t+1)= [symbol] (t)+γ₂·E_{Q}·Vᵥₐₗᵥₑ; and
(3) update of an adaptive parameter:
for α and β, the values thereof are dynamically adjusted by controlling errors and feedback of the flow, and the sensitivity of the total flow Qₜₒₜₐₗ of the main pipeline based on α and β is as follows:
$$\hat{α} ( t + 1 ) = \hat{α} ( t ) + {γ}_{3} \cdot {E}_{Q} \cdot \frac{\partial {Q}_{total}}{\partial α} ,$$
$$\hat{β} ( t + 1 ) = \hat{β} ( t ) + {γ}_{4} \cdot {E}_{Q} \cdot \frac{\partial {Q}_{total}}{\partial β} ,$$
where
$$\frac{\partial {Q}_{total}}{\partial α} and \frac{\partial {Q}_{total}}{\partial β}$$
are sensitivity coefficients with respect to α and β, and are calculated as follows:
$$\frac{\partial {Q}_{total}}{\partial α} = - {k}_{v a l v e} \cdot {( {V}_{v a l v e} )}^{α} \cdot {( {P}_{supply} )}^{β} \cdot ln ( {V}_{v a l v e} ) ;$$
$$\frac{\partial {Q}_{total}}{\partial β} = - {k}_{v a l v e} \cdot {( {V}_{v a l v e} )}^{α} \cdot {( {P}_{supply} )}^{β} \cdot ln ( {P}_{supply} ) ;$$
where γ₁, γ₂, γ₃ and γ₄ are adaptive gains for adjusting a learning rate.

3. The multi-input model-compensated spraying control method for agricultural robots according to claim 2, wherein in S3, in image analysis and data processing, calculation for control is performed for two input cases: the prescription map-based decision system and the vision-based decision system for precision spot spraying; in the processes of prescription map-based spraying and vision-based precision spot spraying, the target flows Q_{nozzle,i,target1} and Q_{nozzle,i,target2} of each nozzle are adjusted as follows based on different inputs:
1) setting the target flow of each nozzle:
the prescription map-based spraying: based on the latitude and longitude position (xᵢ, yᵢ) of each nozzle, the target flow Q_{nozzle,i,target1} of each nozzle is obtained by analyzing a prescription map as:
Q_{nozzle,i,target1}=ƒ_{prescription}(xᵢ,yᵢ);
the vision-based precision spot spraying: based on the crop density and a three-dimensional structure (ρᵢ, hᵢ) identified by the vision-based decision system for precision spot spraying, the target flow Q_{nozzle,i,target2} of each nozzle is calculated as:
Q_{nozzle,i,target2}=gᵥᵢₛᵤₐₗ(ρᵢ,hᵢ);
2) calculating the real-time flow error of each nozzle:
for each nozzle, the real-time flow error ΔQᵢ is calculated:
ΔQᵢ=Q_{nozzle,i,target}−Q_{nozzle,i,actual}
where Q_{nozzle,i,target} is calculated by the prescription map-based decision system or the vision-based decision system for precision spot spraying, and Q_{nozzle,i,actual} is calculated via the pressure and the duty ratio, or is directly measured by a flow sensor;
3) adjusting and calculating the duty ratio for each nozzle:
the duty ratio D_{i,new} of the PWM proportional electromagnetic valve corresponding to the nozzle is adjusted as follows via adaptive control based on the real-time flow error and the target flow:
$${D}_{i , new} = {D}_{i , old} + {K}_{p} \cdot Δ {Q}_{i} \cdot \sqrt{\frac{{P}_{supply}}{{P}_{s e t}}}$$
where ΔQᵢ is the real-time flow error; Kₚ is an adaptive gain; P_{supply} is the pressure of the main pipeline; and Pₛₑₜ is a set pressure;
to deal with a dynamically changing environment and system uncertainties, a compensation term based on pressure feedback is added and enhanced with robustness control, and the adjusted duty ratio is:
$${D}_{i , new} = {D}_{i , new} \cdot ( 1 + {K}_{robust} \cdot \frac{Δ {Q}_{i}}{{Q}_{nozzle , i , target}} )$$
where K_{robust} is a robust gain, allowing the controller to be more adaptable to perturbations and parameter uncertainties;
4) automatically adjusting a gain parameter:
the gain K_{p,i,new} is updated based on the flow error ΔQᵢ and the pressure error ΔPᵢ:
K_{p,i,new}=K_{p,i,old}+μ_{p,i}·(ΔQᵢ·ΔPᵢ)
where K_{p,i,new} is the updated gain parameter; K_{p,i,old} is the gain parameter before updating; and μ_{p,i} is a learning rate for gain adjustment, used to control the size of an update step, ensure smooth updates, and avoid system instability;
ΔQᵢ=Q_{target,i}−Q_{actual,i} is the real-time flow error of the i^{th} nozzle, i.e., the difference between the target flow Q_{target,i} and an actual flow Q_{actual,i}; and ΔPᵢ=Pₛₑₜ−P_{supply,i} is the pressure error of the i^{th} nozzle, i.e., the difference between the set pressure Pₛₑₜ and a real-time pressure P_{supply,i};
the learning rate μ_{p,i} for gain adjustment is adjusted based on a system response; typically, a relatively small learning rate reduces system shock, and a relatively large learning rate accelerates convergence; and the learning rate is adjusted as follows:
$${μ}_{p , i} = \frac{{μ}_{0 , i}}{1 + {α}_{i} \cdot ( Δ {Q}_{i}^{2} + Δ {P}_{i}^{2} )}$$
where μ_{0,i} is an initial learning rate; αᵢ is a learning rate decay coefficient, used to adjust the learning rate based on the flow and the pressure error; and ΔQᵢ and ΔPᵢ are the real-time flow error and the pressure error respectively; and
5) calculating the updated gain:
the gain K_{p,i,new} for each nozzle is calculated as follows:
$${K}_{p , i , n e w} = {K}_{p , i , old} + \frac{{μ}_{0 , i}}{1 + {α}_{i} \cdot ( Δ {Q}_{i}^{2} + Δ {P}_{i}^{2} )} \cdot ( Δ {Q}_{i} \cdot Δ {P}_{i} ) ;$$
the calculated gain K_{p,i,new} is substituted into the equation of the above controller to obtain the duty ratio signal of the PWM proportional electromagnetic valve corresponding to each nozzle as follows:
$${D}_{i , n e w 0} = {D}_{i , old} + {K}_{p , i , new} \cdot Δ {Q}_{i} \cdot \sqrt{\frac{{P}_{supply}}{{P}_{s e t}}} ;$$
$${D}_{i , new} = {D}_{i , n e w 0} \cdot ( 1 + {K}_{robust} \cdot \frac{Δ {Q}_{i}}{{Q}_{nozzle , i , target}} ) ;$$
the difference between the target flow and the actual flow of each nozzle is dynamically adjusted, and the duty ratio is adjusted by using an adaptive gain, to ensure that the flow of the nozzle is precisely controlled in different spraying scenarios and precise spraying is achieved; and
the actual flow of each nozzle is adjusted via the duty ratio of the PWM proportional electromagnetic valve, and both the flow and the pressure are controlled with reference to the pressure feedback.

4. The multi-input model-compensated spraying control method for agricultural robots according to claim 3, wherein in S3, for control of spraying when both the prescription map-based spraying and the vision-based precision spot spraying are not applicable, calculation based on nozzle pressure compensation and local gain adjustment comprises:
1) feeding the nozzle pressure back:
the pressure difference of each nozzle is possible to cause different flows, thus for each nozzle, the duty ratio is corrected via local pressure feedback, the pressure difference of each nozzle is represented by P_{nozzle,i}, and the corrected duty ratio for each nozzle is dynamically adjusted based on the pressure difference in the nozzles;
a global gain K_{global} is introduced to adjust a control output of each nozzle to ensure that the flow of the entire system meets a target requirement, and is achieved by weighting as follows based on the local duty ratio:
$${D}_{i , new} = {D}_{i , o l d} \cdot ( \sqrt{\frac{{P}_{nozzle , i}}{{P}_{set}}} ) \cdot {K}_{global} ;$$
2) performing calculation for adaptive control:
the gain K_{global} is dynamically adjusted by a neural network adaptive algorithm, the pressure difference in the nozzles is calculated by introducing a neural network model, and the gain is automatically adjusted based on the real-time flow error and pressure feedback and is calculated as follows:
K_{global}(t+1)=K_{global}(t)−α·∇J(K_{global})
where K_{global} is a current value of the global gain; a is the learning rate; and ∇J(K_{global}) is a gradient of a loss function with respect to the gain;
the loss function J is a square of the flow error and is calculated as follows:
$$J ( {K}_{global} ) = {{Σ}_{i = 1}^{N} ( {Q}_{nozzle , target} - {Q}_{nozzle , actual} )}^{2} ;$$
3) an equation for comprehensive control of the flow and pressure stabilization of the nozzle is as follows:
$${D}_{i , new} = {D}_{i , old} + {K}_{p} \cdot N \cdot ( {Q}_{nozzle , target} - {Q}_{nozzle , actual} ) \cdot \sqrt{\frac{{P}_{set}}{{P}_{nozzle , i}}} \cdot {K}_{global} .$$
